(19) United States
(12) Patent Application Publication
(10) Pub. No.: US 2009/0021911 A1
(43) Pub. Date: Jan. 22, 2009

(54) FAN ASSEMBLY

(75) Inventors: SHENG-HUNG LEE, Tu-Cheng (TW); LI-PING CHEN, Tu-Cheng (TW); HUNG-CHIEH CHANG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/850,042

(22) Filed: Sep. 5, 2007

(30) Foreign Application Priority Data
Jul. 20, 2007 (CN) 200720200691.5

(51) Int. Cl. H05K 7/20

(52) U.S. Cl. 361/695

(57) ABSTRACT

A fan assembly for dissipating heat from an electronic device, includes a fan bracket (30), a fan module (40), and a chassis (10). The fan bracket has a main body (31), a flange (33) extends out from one side of the main body, the main body defines a recess (36) on the other side thereof, and the recess extends into the flange. The fan module includes a fan (41) and a fastening body (43) attached to a first side of the fan, the fastening body forming a ferruled portion (431), a second side opposite to the first side of the fan received in the recess of the bracket. The chassis has a positioning post (15) formed thereon, for inserting in the ferruled portion of the fastening body.

### BACKGROUND

1. Field of the Invention

The present invention relates to a fan assembly, and more particularly to a fan assembly within a server enclosure for dissipating heat from electronic devices.

2. Description of Related Art

Computer systems typically have multiple power supplies and fans, and each device is usually screwed to a chassis of the computer. If one of these components fails or malfunctions, the component may affect continuing operation of the system until a service technician subsequently replaces the failed component. Unfortunately, some systems do not provide hot-plug components, which enable a service technician to replace the failed component during operation of the system. Thus, replacing the failed component requires shutting down the system and removing screws from the component.

Further, some fixtures are used for latching the fans, such as a fan rack as presented in US patent application 20,040,256,334. A modularized fan rack is installed in a reserved space of electronic equipment for mounting several fans, which comprises a baseboard with a hollow installing section with a plurality of fixtures disposed respectively on two corresponding sides. The distance between any two adjacent fixtures substantially equal to the length of the fan being mounted onto the base board. A ventilation board with a plurality of openings for ventilating air therethrough, is disposed on the surface of one end of the base board. Two sideboards are respectively disposed on both ends of the ventilation board adjacent to the baseboard and on the side away from the baseboard. The same fan being coupled by any two adjacent fixtures and another fixture being disposed adjacent to the fixture for mounting a fan adjacent to the side boards. This fan rack has a lot of components for co-retaining the fans, and assembling the fans to the base board is time-consuming.

What is needed, therefore, is to provide a fan assembly, which has a simple structure, and is easy to maintain.

### SUMMARY

A fan assembly for dissipating heat from an electronic device, the fan assembly includes a fan bracket, a fan module, and a chassis. The fan bracket has a main body, a flange extending out from one side of the main body, the main body defines a recess on the other side thereof, the recess extends into the flange. The fan module includes a fan and a fastening body, which is attached to a first side of the fan, the fastening body forming a ferruled portion, a second side opposite to the first side of the fan received in the recess of the bracket. The chassis has a positioning post formed thereon, the positioning post inserted in the ferruled portion of the fastening body.

Other advantages and novel features of the present invention will become more apparent from the following detailed description of a preferred embodiment when taken in conjunction with the accompanying drawings, in which:

### BRIEF DESCRIPTION OF THE DRAWINGS

FIG. 1 is an exploded, isometric view of a fan assembly according to a preferred embodiment of the present invention, the fan assembly including a fan bracket, a chassis, and a plurality of fan modules;

FIG. 2 is an enlarged, exploded view of a fan module of FIG. 1; and

FIG. 3 is an assembled view of FIG. 1.

### DETAILED DESCRIPTION

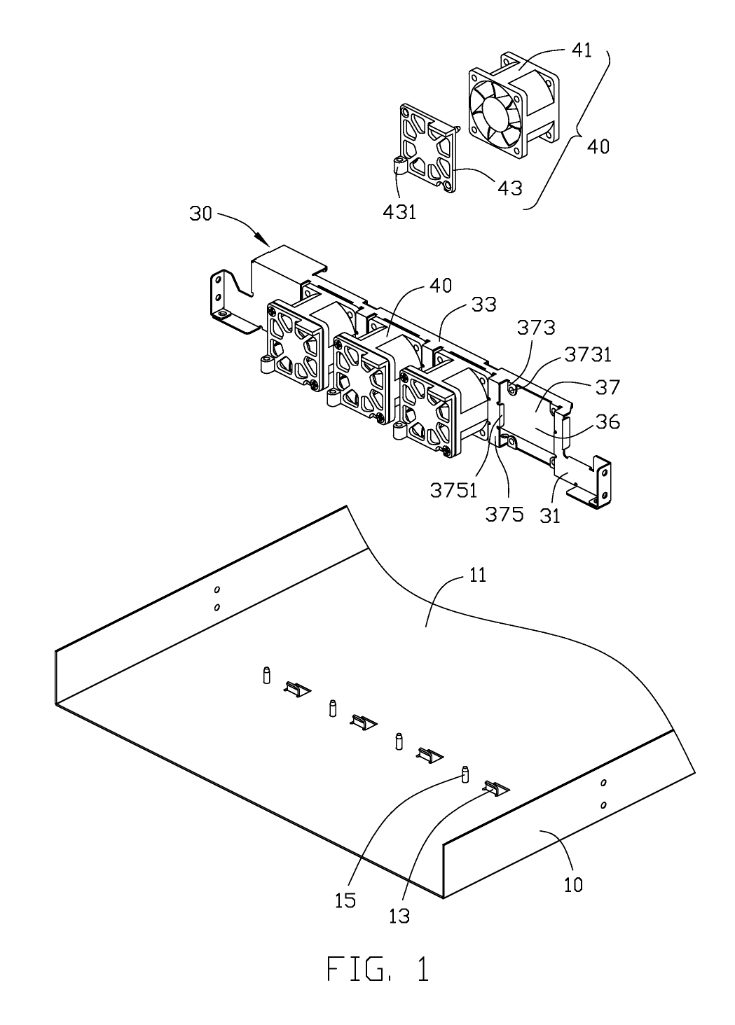

Referring to FIG. 1, a fan assembly in accordance with a preferred embodiment of the present invention includes a fan bracket 30, a chassis 10 configured for receiving the bracket 30, and a plurality of fan modules 40 for dissipating heat from electronic devices (not shown) within the chassis 10.

The chassis 10 includes a bottom panel 11. The bottom panel 11 includes a plurality of columnar positioning posts 15, each of which have a threaded top end, and a plurality of spring clips 13 arranged in such a manner that each fan module 40 is sandwiched between one of the spring clips 13 and the fan bracket 30. The fan bracket 30 has a main body 31. Two flanges 33 extending out perpendicularly from top bottom edges of the main body 31 respectively. The main body 31 having at least one recess 36, the recess 36 receiving the fan module partially therein, and the recess 36 defining a blow opening 37 at a bottom thereof for communicating airflow through the fan bracket 30. At least one stopper portion 373 extends perpendicularly from where each of the flanges 33 meets the recess 36, the stopper portion 373 abutting against the fan modules 40. A pair of tabs 3751 extends into the recess 36 at opposite sides thereof. A width of the recess 36 being substantially equal to a width of the fan module 40, a distance between the spring clips 13 and the corresponding stopper portion 373 being substantially equal to a length of the fan module 40. Each stopper portion 373 has a protuberant portion 3731 for holding a corresponding fan module 40.

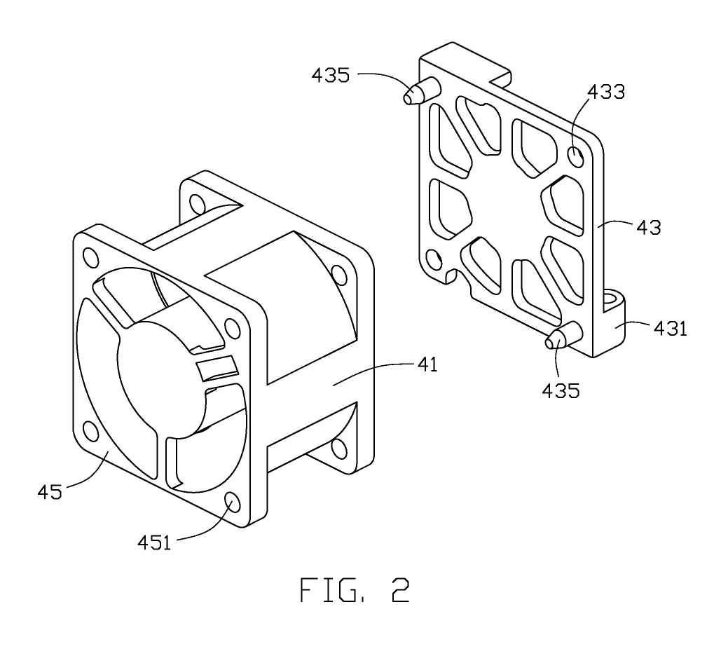

Referring also to FIG. 2, each fan module 40 includes a generally cubic-shaped fan 41 and a similarly cubic-shaped fastening body 43 attached to a first side of the fan 41. A second side of the fan 41 can be received in a corresponding recess 36. The fan 41 has two opposite rectangular sidewalls 45 each defining a fan opening corresponding in size to the recesses 36 of the fan bracket 30. Each sidewall 45 defines a locking hole 451 at each corner thereof. The fastening body 43 has a ferruled portion 431 at a lower corner thereof, and a first fixing pin 435 at one corner thereof opposite the ferruled portion 431. The fastening body 43 forms a second same fixing pin 435 on the opposite corner diagonal to the first fixing pin 435. The fastening body 43 defines a fixing hole 433 at each of the remaining corners thereof.

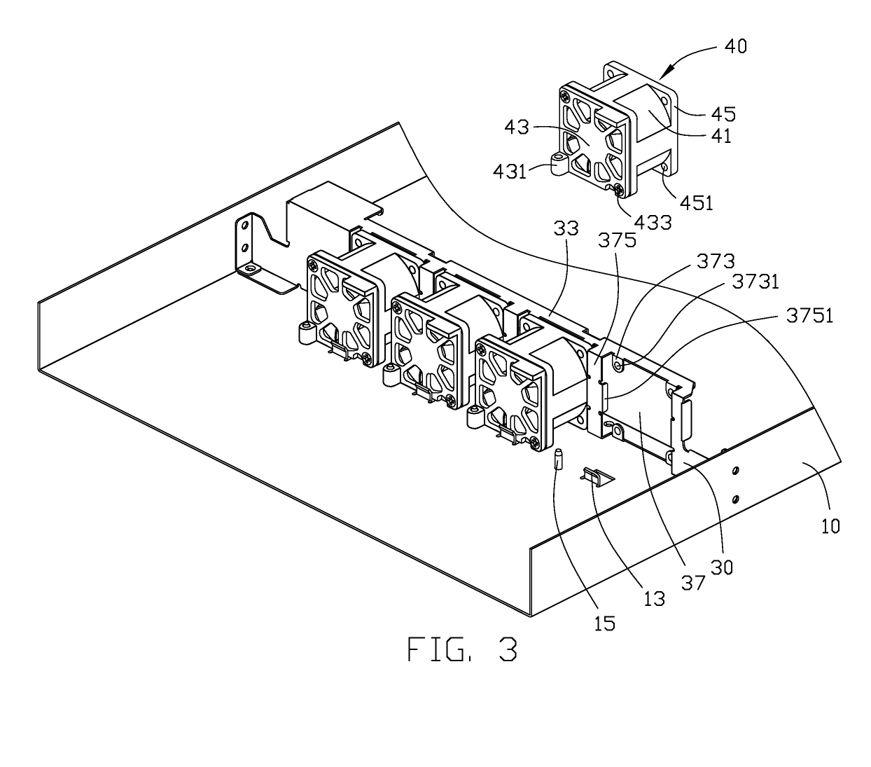

Referring also to FIG. 3, when assembling the fan assembly, the fan bracket 30 is positioned in the chassis 10. Then the fastening body 43 is fastened on the fan 41 with the fixing pins 435 inserted in the locking holes 451 of the fan 41, and two screws are inserted through the fixing holes 433 into the locking holes 451 respectively. Then, the fan module 40 is positioned in the chassis 10 so that one of the columnar positioning posts 15 extends through the ferruled portion 431 and the corresponding spring clip 13 clamps an outside of the fastening body 43. The stopper portions 373 deform back until the protuberant portions 3731 engage in the corresponding locking holes 451, and the tabs 3751 clamp the fan module 40. Then a nut is attached to the threaded top of the columnar positioning post 15. Thus, the fan module 40 is securely mounted to the fan bracket 30, and the steps are repeated for the remaining fan modules 40.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A fan assembly for dissipating heat from an electronic device, the fan assembly comprising:
a fan bracket having a main body, a flange extending out from one side of the main body, the main body defining a recess on the other side thereof, the recess extending into the flange;
a fan module comprising a fan and a fastening body attached to a first side of the fan, the fastening body forming a ferruled portion, a second side opposite to the first side of the fan received in the recess of the bracket; and
a chassis, a positioning post formed on the chassis, the positioning post inserted in the ferruled portion of the fastening body.

2. The fan assembly as described in claim 1, wherein the ferruled portion is formed at a lower portion of the fastening body thereof.

3. The fan assembly as described in claim 2, wherein the fastening body further has a fixing pin at an opposite side thereof with respect to the ferruled portion, the fan defining a locking hole accommodating the fixing pin therein.

4. The fan assembly as described in claim 1, wherein a top portion of each positioning post has an outer thread.

5. The fan assembly as described in claim 1, wherein a spring clip is disposed on the chassis in such a manner that the fan module is sandwiched between the spring clip and the fan bracket.

6. The fan assembly as described in claim 1, wherein the fan bracket defines a plurality of said recesses arrayed side by side for receiving a plurality of said fan modules.

7. The fan assembly as described in claim 1, wherein at least one stopper portion extends perpendicularly from where the flange meets the recess, the stopper portion abutting against the fan modules.

8. The fan assembly as described in claim 1, wherein a pair of tabs extends into the recess at opposite sides thereof.

9. A fan assembly for dissipating heat from an electronic device, the fan assembly comprising:
a chassis forming a spring clip;
at least one fan module placed in the chassis;
a fan bracket having at least one recess, the recesses receiving the fan module therein, the recess defining a blow opening for communicating airflow through the fan bracket, at least one stopper portion extending into the blow opening of the recess, a width of the recess being substantially equal to a width of the fan module, a distance between the spring clip and the stopper portion being substantially equal to a length of the fan module.

10. The fan assembly as described in claim 8, wherein each stopper portion has a protuberant portion, the fan defining a locking hole at each corner thereof corresponding to the protuberant portions.

11. The fan assembly as described in claim 10, wherein each protuberant portion of the stopper portions is received in a corresponding locking hole of the fan module.

12. The fan assembly as described in claim 8, wherein a pair of tabs extends into the recess at opposite sides thereof.

13. The fan assembly as described in claim 8, wherein the spring clip is disposed in such a manner that the fan module is sandwiched between the spring clip and the fan bracket.

14. A fan assembly comprising:
a chassis;
a plurality of positioning posts extending from the chassis;
a fan bracket mounted on the chassis, the fan bracket having a plurality of receptacles;
a plurality of fan modules each having a first end engaged in the respective receptacle and an opposite second end defining a positioning hole with the respective positioning post inserted therein.

15. The fan assembly as described in claim 14, wherein the fan bracket includes a plurality of protrusions arranged in each of the receptacles, the first end of each of the fan modules having a plurality of locking holes engaged with the respective protrusions.
